(19) United States
(12) Patent Application Publication
(10) Pub. No.: US 2026/0190678 A1
(43) Pub. Date: Jul. 2, 2026

(54) DISPLAY DEVICE

(71) Applicant: LG Display Co., Ltd., Seoul (KR)

(72) Inventors: DongYoon LEE, Paju-si (KR); HyunJin KIM, Paju-si (KR); Insu HWANG, Paju-si (KR); Jooyoung PYO, Paju-si (KR)

(73) Assignee: LG Display Co., Ltd., Seoul (KR)

(21) Appl. No.: 19/222,325

(22) Filed: May 29, 2025

(30) Foreign Application Priority Data
Dec. 26, 2024 (KR) 10-2024-0196829

(51) Int. Cl. H10K 59/126; G09G 3/3233; H10K 59/38; H10K 59/80

(52) U.S. Cl. CPC H10K 59/126; H10K 59/38; H10K 59/80515; G09G 3/3233; G09G 2300/0842; G09G 2330/08; G09G 2330/10

(57) ABSTRACT

A display device in one or more examples may include a substrate, a display area in which a first sub-pixel including a first emission area and a first circuit area and a second sub-pixel including a second emission area and a second circuit area are disposed, a shielding pattern disposed on the substrate and located in the first circuit area, a protective layer on the shielding pattern, a color filter disposed on the protective layer, located in the second emission area, and extending from the second emission area toward the first circuit area, a first pixel electrode disposed on the protective layer, located in the first emission area, and extending from the first emission area toward the first circuit area, and a second pixel electrode disposed on the color filter, located in the second emission area, and extending from the second emission area toward the first circuit area.

### CROSS REFERENCE TO RELATED APPLICATION

This application claims the benefit of and priority to Korean Patent Application No. 10-2024-0196829, filed on Dec. 26, 2024, the entire contents of which are incorporated herein by reference for all purposes as if fully set forth herein.

### BACKGROUND

### 1. Technical Field

Embodiments of the present disclosure relate to a display device.

### 2. Description of Related Art

In the manufacturing process of a display panel, defects may occur in which the sub-pixel becomes a bright spot or dark spot due to various reasons, such as foreign matter occurring at various locations within the sub-pixel. For example, a transistor within each sub-pixel may be formed through a lot of processes, and a foreign matter may occur in the transistor during this process. If a foreign matter occurs in the transistor, a short circuit or open circuit phenomenon may occur due to the foreign matters. Due to this phenomenon, the sub-pixel may become a defective sub-pixel that does not emit light normally. This may reduce the yield of the display panel.

The description of related art should not be considered prior art merely because it is mentioned in or associated with this section. The description of related art includes information that describes one or more aspects of the subject technology, and the description in this section does not limit the scope of the invention.

### SUMMARY

Embodiments of the present disclosure may provide a display device having a structure that enables repair processing to normalize a defective sub-pixel.

Embodiments of the present disclosure may provide a display device having a structure that enables repair processing without reducing the aperture ratio.

Embodiments of the present disclosure may provide a high resolution display device capable of repair processing.

Embodiments of the present disclosure may provide a display device capable of utilizing a pattern formed for display as a repair pattern.

Embodiments of the present disclosure may provide a display device capable of manufacturing a display panel into a good product through a repair processing of a defective sub-pixel in the manufacturing process, thereby increasing the panel manufacturing yield, saving production energy, and enabling process optimization.

The aspects of the embodiments of the present disclosure are not limited to the aspects described in this specification, and other aspects will be clearly understood by those skilled in the art from the description below.

A display device according to embodiments of the present disclosure may include a substrate, a display area in which a first sub-pixel including a first emission area and a first circuit area and a second sub-pixel including a second emission area and a second circuit area are disposed, a shielding pattern disposed on the substrate and located in the first circuit area, a protective layer on the shielding pattern, a color filter disposed on the protective layer, located in the second emission area, and extending from the second emission area toward the first circuit area, a first pixel electrode disposed on the protective layer, located in the first emission area, and extending from the first emission area toward the first circuit area, and a second pixel electrode disposed on the color filter, located in the second emission area, and extending from the second emission area toward the first circuit area.

A display device according to embodiments of the present disclosure may include a first color filter located in a first emission area of a first sub-pixel, a first sub-pixel circuit located in a first circuit area of the first sub-pixel, a second color filter located in a second emission area of a second sub-pixel adjacent to the first sub-pixel in a first direction, a second sub-pixel circuit located in a second circuit area of the second sub-pixel, and a pixel electrode layer located in the first emission area, the first circuit area, the second emission area, and the second circuit area. The second color filter may include an extended portion extending beyond the second emission area toward the first circuit area. The pixel electrode layer may be disconnected near the extended portion of the second color filter.

According to embodiments of the present disclosure, it is possible to provide a display device having a structure that enables repair processing to normalize a defective sub-pixel.

According to embodiments of the present disclosure, it is possible to provide a display device having a structure that enables repair processing without reducing the aperture ratio.

According to embodiments of the present disclosure, it is possible to provide a high resolution display device capable of repair processing.

According to embodiments of the present disclosure, it is possible to provide a display device capable of utilizing a pattern formed for display as a repair pattern.

According to embodiments of the present disclosure, it is possible to provide a display device capable of manufacturing a display panel into a good product through a repair processing of a defective sub-pixel in the manufacturing process, thereby increasing the panel manufacturing yield, saving production energy, and enabling process optimization.

The effects of the embodiments of the present disclosure are not limited to the effects described in this specification, and other effects will be clearly understood by those skilled in the art from the description of the claims.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a system configuration diagram of a display device according to embodiments of the present disclosure.

FIG. 2 illustrates a display panel according to embodiments of the present disclosure.

FIG. 3 illustrates a sub-pixel of a display panel according to embodiments of the present disclosure.

FIG. 4 is a plan view of a display panel according to embodiments of the present disclosure.

FIG. 5 is a plan view of an area of a first sub-pixel and a second sub-pixel of a display panel according to embodiments of the present disclosure.

FIGS. 6 to 8 are cross-sectional views of an area of a display panel where the first to third sub-pixels are disposed according to embodiments of the present disclosure.

FIGS. 9 and 10 are plan views and cross-sectional views of a portion of a display panel according to embodiments of the present disclosure.

FIGS. 11 to 15 illustrate a manufacturing process of a display panel according to embodiments of the present disclosure.

FIG. 16 is a cross-sectional view of a portion of a display panel according to embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting”, “make up of”, and “formed of” used herein are generally intended to allow other components to be added unless the terms are used with the term “only”. As used herein, singular forms are intended to include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps”, etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after”, “subsequent to”, “next”, “before”, and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

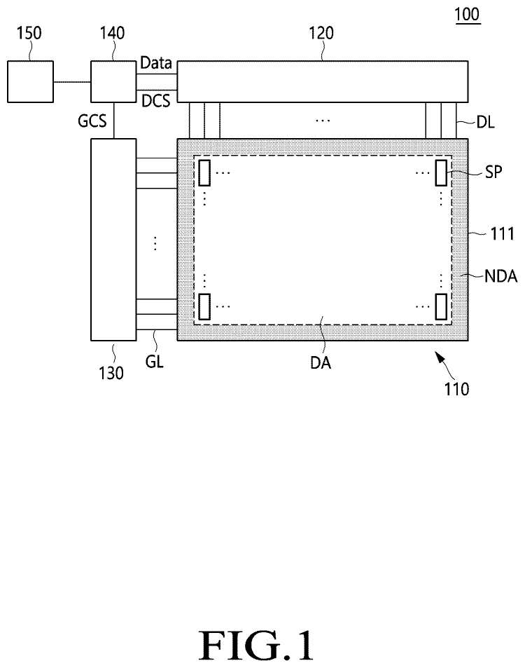

FIG. 1 is a system configuration diagram of a display device 100 according to embodiments of the present disclosure.

Referring to FIG. 1, a display device 100 according to embodiments of the present disclosure may include a display panel 110 and a driving circuit for driving the display panel 110.

The driving circuit may include a data driving circuit 120 and a gate driving circuit 130, and may further include a controller 140 for controlling the data driving circuit 120 and the gate driving circuit 130.

The display panel 110 may include a substrate 111 and signallines such as a plurality of data lines DL and a plurality of gate lines GL disposed on the substrate 111. The display panel 110 may include a plurality of sub-pixels SP connected to a plurality of data lines DL and a plurality of gate lines GL.

The display panel 110 or substrate 111 may include a display area DA where an image is displayed and a non-display area NDA where an image is not displayed. The display area DA may include a plurality of sub-pixels SP for displaying an image, and a plurality of signal lines (for example, a plurality of data lines DL, a plurality of gate lines GL) connected to the plurality of sub-pixels SP, and the non-display area NDA may include a pad portion to which circuit components are electrically connected, and a plurality of link lines that electrically connect a plurality of signal lines arranged in the display area DA to the pad portion.

As an example, the circuit component electrically connected to the pad portion may include at least one source driver integrated circuit implementing a data driving circuit 120, or may include at least one flexible printed circuit (also called a circuit film) on which at least one source driver integrated circuit is mounted. As another example, the circuit component electrically connected to the pad portion may include at least one gate driver integrated circuit implementing a gate driving circuit 130, or may include at least one flexible printed circuit (also called a circuit film) having at least one gate driver integrated circuit mounted thereon. As another example, the circuit component electrically connected to the pad portion may include a printed circuit board.

The data driving circuit 120 may output data signals to the plurality of data lines DL for driving a plurality of data lines DL.

The gate driving circuit 130 may output gate signals to the plurality of gate lines GL for driving a plurality of gate lines GL.

The controller 140 may supply a data control signal DCS to the data driving circuit 120 to control the operation timing of the data driving circuit 120, and may supply a gate control signal GCS to the gate driving circuit 130 to control the operation timing of the gate driving circuit 130.

The controller 140 may start scanning according to the timing implemented in each frame, may convert the input image data input from the outside to fit the data signal format used in the data driving circuit 120, and may supply converted image data Data to the data driving circuit 120 and control data driving at an appropriate time according to the scan.

The controller 140 may receive various timing signals including a vertical synchronization signal VSYNC, a horizontal synchronization signal HSYNC, an input data enable signal DE, a clock signal (LK) in addition to the input image data from the outside (e.g., the host system 150).

In order to control the data driving circuit 120 and the gate driving circuit 130, the controller 140 may receive timing signals such as a vertical synchronization signal VSYNC, a horizontal synchronization signal HSYNC, an input data enable signal DE, and a clock signal CLK, and generate various control signals and output to the data driving circuit 120 and the gate driving circuit 130. Here, the control signals may include a data driving control signal DCS and a gate driving control signal GCS.

The data driving circuit 120 may include one or more source driver integrated circuits SDIC.

For example, each source driver integrated circuit SDIC may be connected to the display panel 110 using a tape automated bonding (TAB) method, or may be connected to the bonding pad of the display panel 110 using a chip-on-glass (COG) or chip-on-panel (COP) method, or may be implemented using a chip-on-film (COF) method and connected to the display panel 110.

The data driving circuit 120 may be connected to one side (e.g., the upper or lower side) of the display panel 110. Depending on the driving method or panel design method, the data driving circuit 120 may be connected to both sides (e.g., upper and lower sides) of the display panel 110, or may be connected to two or more of the four sides of the display panel 110.

The gate driving circuit 130 may be connected to the display panel 110 using a tape automated bonding (TAB) method, or may be connected to a bonding pad of the display panel 110 using a chip-on-glass (COG) or chip-on-panel (COP) method, or may be connected to the display panel 110 according to a chip-on-film (COF) method. Alternatively, the gate driving circuit 130 may be a gate-in-panel (GIP) type, and may be formed in the non-display area NDA of the display panel 110. The gate driving circuit 130 may be disposed on or connected to the substrate SUB. That is, if the gate driving circuit 130 is of the GIP type, it may be disposed in the non-display area NDA of the substrate 111. The gate driving circuit 130 may be connected to the substrate 111 in the case of a chip-on-glass (COG) type, chip-on-film (COF) type, etc.

Meanwhile, at least one of the data driving circuit 120 and the gate driving circuit 130 may be disposed in the display area DA. For example, the gate driving circuit 130 may be disposed in the display area DA. In this case, the gate driving circuit 130 may be disposed over the entire display area DA or only in a portion of the display area DA. The gate driving circuit 130 may be disposed not to overlap the sub-pixels SP, or may be disposed to partially or entirely overlap the sub-pixels SP.

As another example, the data driving circuit 120 may be disposed in the display area DA. In this case, the data driving circuit 120 may be disposed throughout the entire display area DA or only in a portion of the display area DA. The data driving circuit 120 may be disposed not to overlap the sub-pixels SP, or may be disposed to partially or entirely overlap the sub-pixels SP.

The gate driving circuit 130 may be connected to one side (e.g., left or right) of the display panel 110. Depending on the driving method or panel design method, the gate driving circuit 130 may be connected to both sides (e.g., left and right) of the display panel 110, or may be connected to two or more of the four sides of the display panel 110.

The controller 140 may be mounted on a printed circuit board, a flexible printed circuit, etc., and may be electrically connected to the data driving circuit 120 and the gate driving circuit 130 through a printed circuit board, a flexible printed circuit.

The display device 100 according to embodiments of the present disclosure may be a self-luminous display device in which the display panel 110 can emit light on its own. For example, the display device 100 according to embodiments of the present disclosure may be one of the display devices including an organic light emitting diode (OLED) display device, a quantum dot display, and a micro light emitting diode (Micro LED) display device.

If the display device 100 according to embodiments of the present disclosure is an organic light emitting diode display device, each sub-pixel SP may include an organic light emitting diode which emits light by itself as a light emitting device. If the display device 100 according to embodiments of the present disclosure is a quantum dot display device, each sub-pixel SP may include a light emitting device made of quantum dots, which are semiconductor crystals which emit light on their own. If the display device 100 according to embodiments of the present disclosure is a micro light emitting diode display device, each sub-pixel SP may include a micro light emitting diodes, which emit light on their own and are made based on inorganic materials, as a light emitting device.

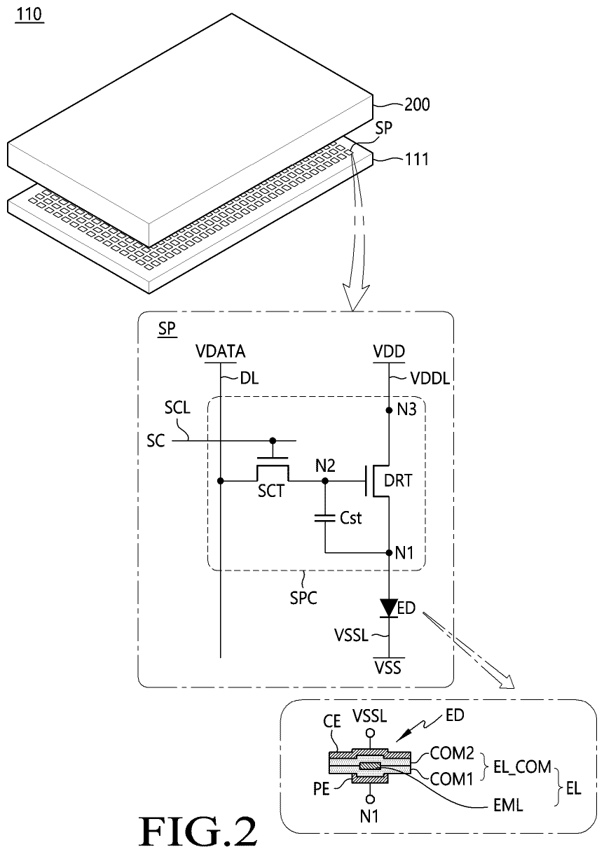

FIG. 2 illustrates a display panel 110 according to embodiments of the present disclosure.

Referring to FIG. 2, the display panel 110 may include a substrate 111 disposed in a plurality of sub-pixels SP and an encapsulation layer 200 on the substrate 111. Here, the encapsulation layer 200 may also be referred to as an encapsulation substrate or an encapsulation portion.

If the display device 100 according to embodiments of the present disclosure is a self-luminous display device, each of the plurality of sub-pixels SP disposed on the substrate 111 may include a light emitting device ED and a sub-pixel circuit SPC for driving the light emitting device ED.

The sub-pixel circuit SPC may drive the light emitting device ED by supplying a driving current to the light emitting device ED at a predetermined timing. The light emitting device ED may be driven by the driving current to emit light.

The sub-pixel circuit SPC may include a plurality of pixel driving transistors and at least one capacitor for driving the light emitting device ED. For example, the sub-pixel circuit SPC may include a driving transistor DRT for driving the light emitting device ED, a scan transistor SCT that is turned on according to a scan signal SC to transmit the data voltage VDATA to a gate node of the driving transistor DRT, and a storage capacitor Cst.

The light emitting device ED may include a pixel electrode PE, an intermediate layer EL, and a common electrode CE. The intermediate layer EL may be disposed between the pixel electrode PE and the common electrode CE. For example, the light emitting device ED may be an organic light emitting diode (OLED), an inorganic-based light emitting diode (LED), or a quantum dot light emitting device. For example, if the light emitting device ED is an organic light emitting diode (OLED), the intermediate layer EL in the light emitting device ED may include an organic film containing an organic material.

In the case that the light emitting device ED is an organic light emitting diode, the intermediate layer EL may include the emission layer EML and a common intermediate layer EL_COM. The common intermediate layer EL_COM may include a first common intermediate layer COM1 and a second common intermediate layer COM2. The first common intermediate layer COM1 may be disposed between the pixel electrode PE and the emission layer EML, and may include at least one layer (e.g., an organic film). The second common intermediate layer COM2 may be disposed between the emission layer EML and the common electrode CE, and may include at least one layer (e.g., an organic film). For example, the first common intermediate layer COM1 may include a hole injection layer HIL and a hole transfer layer HTL. Among the common intermediate layers EL_COM, the second common intermediate layer COM2 may include an electron transfer layer ETL and an electron injection layer EIL.

For example, the emission layer EML may be disposed in each of the plurality of sub-pixels SP, or in another example, may be commonly disposed in the plurality of sub-pixels SP. The common intermediate layer EL_COM may be commonly disposed across the plurality of sub-pixels SP. For example, the emission layer EML may overlap with the emission area. For another example, the emission layer EML may overlap with the emission area and the non-emission area. The common intermediate layer EL_COM may overlap with a plurality of emission areas and the non-emission area.

The pixel electrode PE may be an electrode disposed in each sub-pixel SP, and the common electrode CE may be an electrode commonly disposed in a plurality of sub-pixels SP. For example, the pixel electrode PE may be an anode and the common electrode CE may be a cathode. For another example, the pixel electrode PE may be a cathode and the common electrode CE may be an anode. For example, the common electode CE may be electrically connected to a second common voltage line VSSL. A second common voltage VSS, which is a type of common voltage, may be applied to the common electode CE through the second common voltage line VSSL. The pixel electrode PE may be electrically connected directly or indirectly (via another transistor) to a first node N1 of the driving transistor DRT of each sub-pixel SP. In the present disclosure, “second common voltage VSS” may also be referred to as “base voltage VSS”, and “second common voltage line VSSL” may be referred to as “base voltage line VSSL”.

The driving transistor DRT may supply driving current to the light emitting device ED. The driving transistor DRT may be connected between a first common voltage line VDDL and the light emitting device ED.

The driving transistor DRT may include a first node N1, a second node N2, and a third node N3. The first node N1 may be electrically connected to the light emitting device ED. The third node N3 may be electrically connected to the first common voltage line VDDL. The second node N2 may be connected to a scan transistor SCT. A data signal VDATA may be applied to the second node N2.

In the driving transistor DT, the second node N2 may be a gate node, the first node N1 may be a source node or a drain node, and the third node N3 may be a drain node or a source node. Hereinafter, for convenience of explanation, it will be described a case in which the second node N2 is a gate node, the first node N1 is a source node, and the third node N3 is a drain node in the driving transistor DRT.

The scan transistor SCT may transmit a data signal VDATA, which is an image signal, to the second node N2 which is the gate node of the driving transistor DRT.

The scan transistor SCT may be controlled on-off by the scan signal SC which is a gate signal applied through the scan line SCL as a type of gate line GL, and may control the electrical connection between the second node N2 of the driving transistor DRT and the data line DL. The drain electrode or source electrode of the scan transistor SCT may be electrically connected to the data line DL, and the source electrode or drain electrode of the scan transistor SCT may be electrically connected to the second node N2 of the driving transistor DRT. The gate electrode of the scan transistor SCT may be electrically connected to the scan line SCL.

The storage capacitor Cst may be electrically connected between the first node N1 and the first node N2 of the driving transistor DRT. The storage capacitor Cst may include a first capacitor electrode electrically connected to the first node N1 of the driving transistor DRT or corresponding to the first node N1 of the driving transistor DRT, and a second capacitor electrode electrically connected to the second node N2 of the driving transistor DRT or corresponding to the second node N2 of the driving transistor DRT.

The storage capacitor Cst may be an external capacitor intentionally designed outside the driving transistor DRT rather than a parasitic capacitor (e.g., Cgs, Cgd) as an internal capacitor which may exist between the first node N1 and the second node N2 of the driving transistor DRT.

Each of the driving transistor DRT and the scan transistor SCT may be an n-type transistor or a p-type transistor.

The display panel 110 may have a top emission structure or a bottom emission structure.

In the case that the display panel 110 has a top emission structure, at least a portion of the sub-pixel circuit SPC may overlap with at least a portion of the light emitting device ED in a vertical direction. Accordingly, there may be increased the area of the emission area the aperture ratio.

If the display panel 110 has a bottom emission structure, the sub-pixel circuit SPC may not overlap with the light emitting device ED in the vertical direction.

As shown in FIG. 2, the sub-pixel circuit SPC may have 2T-1C structure including two transistors DRT and SCT and one capacitor Cst, however, is not limited thereto. The sub-pixel circuit SPC may further include one or more transistors or one or more capacitors.

Depending on the structure of the sub-pixel circuit SPC, there may vary the type and number of gate signal and/or gate lines supplied to the sub-pixel SP. In addition, depending on the structure of the sub-pixel circuit SPC, there may vary the type and number of common voltages supplied to the sub-pixel SP.

Since circuit elements within each sub-pixel SP (in particular, light emitting devices EDs implemented with organic light emitting diodes (OLEDs) containing organic materials) are vulnerable to external moisture or oxygen, an encapsulation layer 200 may be disposed on the display panel 110 to prevent oxygen from penetrating into the circuit elements (particularly, the light emitting device ED). The encapsulation layer 200 may be configured in various shapes to prevent the light emitting device ED from coming into contact with moisture or oxygen.

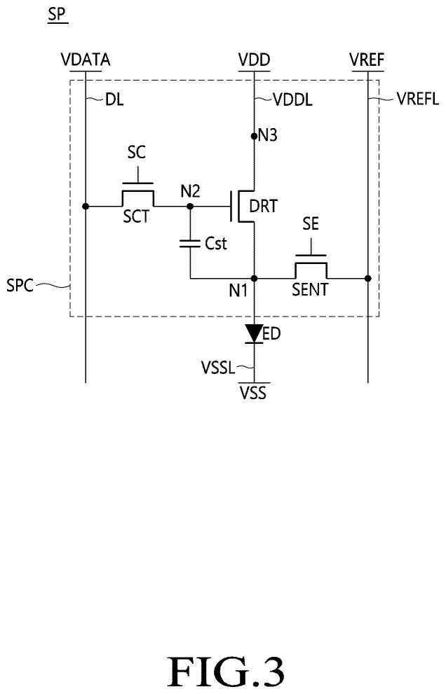

FIG. 3 illustrates a sub-pixel SP of a display panel 110 according to embodiments of the present disclosure. In the following description, FIG. 1 and FIG. 2 are also referred to.

Each of the plurality of sub-pixels SP disposed on the display panel 110 of the display device 100 according to embodiments of the present disclosure may further include a sensing transistor SENT compared to a sub-pixel SP shown in FIG. 2.

Referring to FIG. 3, the sensing transistor SENT may be controlled by a sensing signal SE, which is a type of gate signal, and may be connected between the first node N1 of the driving transistor DRT and a reference voltage line VREFL. That is, the sensing transistor SENT may control the connection between the reference voltage line VREFL and the first node N1 of the driving transistor DRT by being turned on or off according to the sensing signal SE.

The sensing transistor SENT may be turned on by the sensing signal SE having a turn-on level voltage, and may transfer a reference voltage VREF supplied from the reference voltage line VREFL to the first node N1 of the driving transistor DRT. Here, the reference voltage VREF may be a type of common voltage.

In addition, the sensing transistor SENT may be turned on by the sensing signal SE having a turn-on level voltage, and may transfer the voltage of the first node N1 of the driving transistor DRT to the reference voltage line VREFL.

The sensing transistor SENT may be an n-type transistor or a p-type transistor. In this disclosure, for convenience of explanation, it is described an n-type sensing transistor SENT as an example.

For example, a scan signal line SCL transmitting a scan signal SC to a gate node of a scan transistor SCT and a sensing signal line SENL transmitting a sensing signal SE to a gate node of a sensing transistor SENT may be different gate lines. In this case, the scan signal SC and the sensing signal SE may be separate gate signals, and the on-off timing of the scan transistor SCT and the on-off timing of the sensing transistor SENT in one sub-pixel SP may be independent.

As another example, a scan signal line SCL transmitting a scan signal SC to a gate node of a scan transistor SCT and a sensing signal line SENL transmitting a sensing signal SE to a gate node of a sensing transistor SENT may be the same gate line GL. That is, the gate node of the scan transistor SCT and the gate node of the sensing transistor SENT within one sub-pixel SP may be connected to one gate line GL. In this case, the scan signal SC and the sensing signal SE may be the same gate signal, and the on-off timing of the scan transistor SCT and the on-off timing of the sensing transistor SENT within one sub-pixel SP may be the same.

Each of the data line DL, the first common voltage line VDDL, and the reference voltage line VREFL may extend in a first direction (e.g., in the column direction). The gate line GL, such as the scan signal line and the sensing signal line, may extend in a second direction (e.g., in the row direction) different from the first direction.

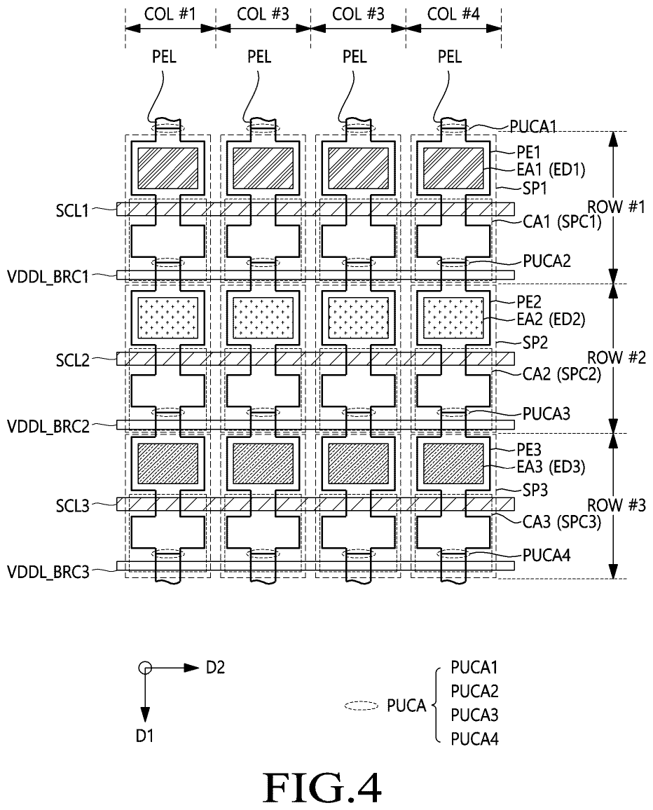

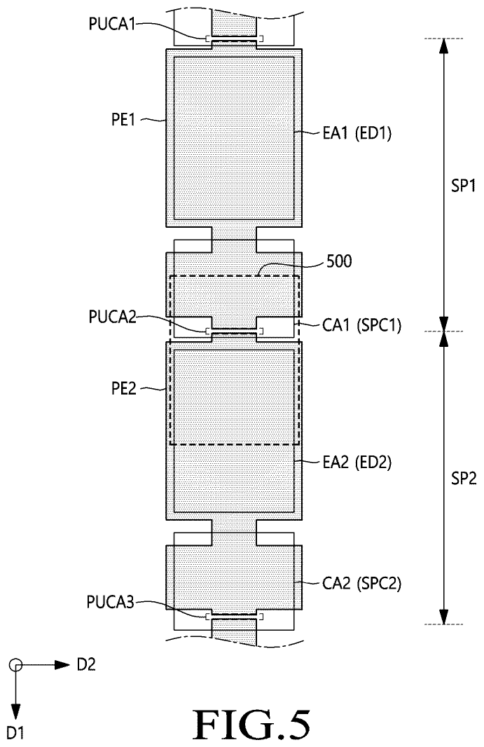

FIG. 4 is a plan view of a display panel 110 according to embodiments of the present disclosure, and FIG. 5 is a plan view of an area of a first sub-pixel SP1 and a second sub-pixel SP2 of a display panel 110 according to embodiments of the present disclosure. In the following description, FIGS. 1 to 3 are also referred to.

In the display panel 110 according to the embodiments of the present disclosure, a plurality of sub-pixels SP may be arranged in a matrix form. The display panel 110 may include a plurality of sub-pixel rows ROW #1, ROW #2 and ROW #3. The display panel 110 may include a plurality of sub-pixel columns COL #1, COL #2, COL #3 and SPC #4.

Hereinafter, a first direction and a second direction are described as two directions. As an example, the first direction may be a column direction, and the second direction may be a row direction. As another example, the first direction may be a row direction, and the second direction may be a column direction. Hereinafter, for the convenience of explanation, the first direction is described as a column direction, and the second direction is described as a row direction, but is not limited thereto.

Each of the plurality of sub-pixel rows ROW #1, ROW #2 and ROW #3 may include a plurality of sub-pixels SP. Each of the plurality of sub-pixels SP may include a emission area and a circuit area. A light emitting device ED may be disposed in the emission area, and a sub-pixel circuit SPC may be disposed in the circuit area.

Each of the plurality of sub-pixel rows ROW #1, ROW #2 and ROW #3 may have a scan signal line SCL1, SCL2 and SCL3 extending in the second direction (e.g., in the row direction).

Each of the plurality of sub-pixel rows ROW #1, ROW #2 and ROW #3 may have a plurality of signal lines (VDDL_BRC1, VDDL_BRC2 and VDDL_BRC3, hereinafter referred to as branch signal lines) extending in the second direction (e.g., in the row direction) and transmitting a common voltage. For example, the first to third branch signal lines VDDL_BRC1, VDDL_BRC2 and VDDL_BRC3 may transmit a first common voltage VDD as a type of common voltage. For example, the first to third branch signal lines VDDL_BRC1, VDDL_BRC2 and VDDL_BRC3 may be sub-signal lines transmitting the first common voltage VDD, and may be electrically connected to a first common voltage line VDDL extending in the first direction (e.g., column direction). Here, the first common voltage line VDDL may be a main signal line transmitting a first common voltage VDD.

Referring to FIG. 4, a plurality of sub-pixel rows may include a first sub-pixel row ROW #1, a second sub-pixel row ROW #2, and a third sub-pixel row ROW #3.

The first sub-pixel row ROW #1 may include a plurality of first sub-pixels SP1 that are arranged adjacently in a second direction (e.g., row direction).

Each of the plurality of first sub-pixels SP1 included in the first sub-pixel row ROW #1 may include a first emission area EA1 and a first circuit area CA1. The first emission area EA1 may include a first light emitting device ED1, and the first circuit area CA1 may include a first sub-pixel circuit SPC1.

In the first sub-pixel row ROW #1, there may be arranged a first scan signal line SCL1 for transmitting a first scan signal to the plurality of first sub-pixels SP1 and a first branch signal line VDDL_BRC1 for transmitting a first common voltage VDD to the plurality of first sub-pixels SP1.

The second sub-pixel row ROW #2 may include a plurality of second sub-pixels SP2 arranged adjacently in the second direction (e.g., row direction).

Each of the plurality of second sub-pixels SP2 included in the second sub-pixel row ROW #2 may include a second emission area EA2 and a second circuit area CA2. The second emission area EA2 may include a second light emitting device ED2, and the second circuit area CA2 may include a second sub-pixel circuit SPC2.

In the second sub-pixel row ROW #2, there may be arranged a second scan signal line SCL2 for transmitting a second scan signal to a plurality of second sub-pixels SP2 and a second branch signal line VDDL_BRC2 for transmitting a first common voltage VDD to a plurality of second sub-pixels SP2.

The third sub-pixel row ROW #3 may include a plurality of third sub-pixels SP3 that are arranged adjacently in the second direction (e.g., in the row direction).

Each of the plurality of third sub-pixels SP3 included in the third sub-pixel row ROW #3 may include a third emission area EA3 and a third circuit area CA4. The third emission area EA3 may include a third light emitting device ED3, and the third circuit area CA4 may include a third sub-pixel circuit SPC3.

In the third sub-pixel row ROW #3, there may be arranged a third scan signal line SCL3 for transmitting a third scan signal to a plurality of third sub-pixels SP3 and a third branch signal line VDDL_BRC3 for transmitting a first common voltage VDD to a plurality of third sub-pixels SP3.

Referring to FIG. 4, the plurality of sub-pixel columns may include a first sub-pixel column COL #1, a second sub-pixel column COL #2, a third sub-pixel column COL #3, and a fourth sub-pixel column COL #4.

Each of the first sub-pixel column COL #1, the second sub-pixel column COL #2, the third sub-pixel column COL #3, and the fourth sub-pixel column COL #4 may include a first sub-pixel SP1, a second sub-pixel SP2, and a third sub-pixel SP3.

The display panel 110 according to embodiments of the present disclosure may further include a pixel electrode layer PEL disposed in each of the plurality of sub-pixel columns COL #1, COL #2, COL #3 and COL #4.

The plurality of pixel electrode layers PEL may include a first pixel electrode layer PEL disposed in a first sub-pixel column COL #1, a second pixel electrode layer PEL disposed in a second sub-pixel column COL #2, a third pixel electrode layer PEL disposed in a third sub-pixel column COL #3, and a fourth pixel electrode layer PEL disposed in a fourth sub-pixel column COL #4.

Each of the plurality of pixel electrode layers PEL may include a plurality of pixel undercut areas PUCA. Each of the plurality of pixel undercut areas PUCA may be located at or near a boundary of two adjacent sub-pixels SP. Each of the plurality of pixel undercut areas PUCA may be a point where a corresponding pixel electrode layer is disconnected or connected.

For example, the first pixel electrode layer PEL may be disconnected in each of the plurality of pixel undercut areas PUCA1, PUCA2, PUCA3 and PUCA4. As another example, the first pixel electrode layer PEL may be connected in at least one pixel undercut area among the plurality of pixel undercut areas PUCA1, PUCA2, PUCA3 and PUCA4, and the first pixel electrode layer PEL may be disconnected in the remaining pixel undercut areas.

For example, the second pixel electrode layer PEL may be disconnected in each of the plurality of pixel undercut areas PUCA1, PUCA2, PUCA3 and PUCA4. As another example, the second pixel electrode layer PEL may be connected in at least one pixel undercut area among the plurality of pixel undercut areas PUCA1, PUCA2, PUCA3 and PUCA4, and the second pixel electrode layer PEL may be disconnected in the remaining pixel undercut areas.

For example, the third pixel electrode layer PEL may be disconnected in each of the plurality of pixel undercut areas PUCA1, PUCA2, PUCA3 and PUCA4. As another example, the third pixel electrode layer PEL may be connected in at least one pixel undercut area among the plurality of pixel undercut areas PUCA1, PUCA2, PUCA3 and PUCA4, and the third pixel electrode layer PEL may be disconnected in the remaining pixel undercut areas.

For example, the fourth pixel electrode layer PEL may be disconnected in each of the plurality of pixel undercut areas PUCA1, PUCA2, PUCA3 and PUCA4. As another example, the fourth pixel electrode layer PEL may be connected in at least one pixel undercut area among the plurality of pixel undercut areas PUCA1, PUCA2, PUCA3 and PUCA4, and the fourth pixel electrode layer PEL may be disconnected in the remaining pixel undercut areas.

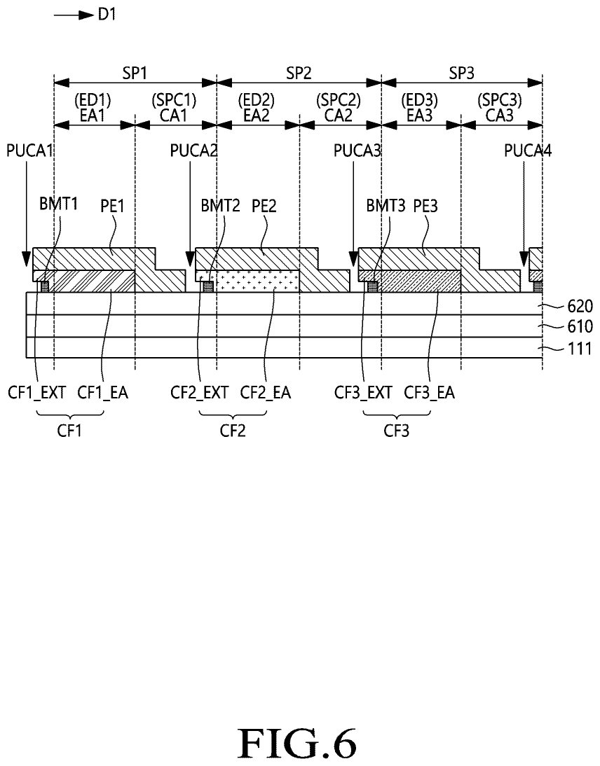

FIG. 6 is a cross-sectional view of the display panel 110 where the first to third sub-pixels SP1, SP2 and SP3 are arranged. FIG. 6 is a cross-sectional view of the region in which the first to third sub-pixels SP1, SP2 and SP3 included in the first sub-pixel column COL #1 are arranged. FIGS. 1 to 5 are also referred in the following description.

Referring to FIG. 6, the first to third sub-pixels SP1, SP2 and SP3 may be adjacent to each other in the first direction. The first sub-pixel SP1 may include a first emission area EA1 in which a first light emitting device ED1 is disposed and a first circuit area CA1 in which a first sub-pixel circuit SPC1 is disposed. The second sub-pixel SP2 adjacent to the first sub-pixel SP1 in the first direction may include a second emission area EA2 in which a second light emitting device ED2 is disposed and a second circuit area CA2 in which a second sub-pixel circuit SPC2 is disposed. The third sub-pixel SP3 adjacent to the second sub-pixel SP2 in the first direction may include a third emission area EA3 in which a third light emitting device ED3 is disposed and a third circuit area CA4 in which a third sub-pixel circuit SPC3 is disposed.

A display panel 110 according to embodiments of the present disclosure may include a first color filter CF1 located in a first emission area EA1 of a first sub-pixel SP1, a first sub-pixel circuit SPC1 located in a first circuit area CA1 of a first sub-pixel SP1, a second color filter CF2 located in a second emission area EA2 of a second sub-pixel SP2, a second sub-pixel circuit SPC2 located in a second circuit area CA2 of a second sub-pixel SP2, a third color filter CF3 located in a third emission area EA3 of a third sub-pixel SP3, and a third sub-pixel circuit SPC3 located in a third circuit area CA4 of a third sub-pixel SP3.

The display panel 110 according to the embodiments of the present disclosure may further include a pixel electrode layer PEL disposed on the first color filter CF1, the second color filter CF2, and the third color filter CF3.

The pixel electrode layer PEL may be disposed in the first emission area EA1, the first circuit area CA1, the second emission area EA2, the second circuit area CA2, the third emission area EA3, and the third circuit area CA4.

In the second pixel undercut area PUCA2 at or near the boundary between the first sub-pixel SP1 and the second sub-pixel SP2, the pixel electrode layer PEL may be disconnected. In the third pixel undercut area PUCA3 at or near the boundary between the second sub-pixel SP2 and the third sub-pixel SP3, the pixel electrode layer PEL may be disconnected. In the fourth pixel undercut area PUCA4 at or near the boundary between the third sub-pixel SP3 and the fourth sub-pixel SP4, the pixel electrode layer PEL may be disconnected. The fourth sub-pixel SP4 may be a sub-pixel adjacent to the third sub-pixel SP3 in the first direction.

Accordingly, the first pixel electrode PE1, the second pixel electrode PE2, and the third pixel electrode PE3 may be configured to be separated or disconnected. As a result, the first light emitting device ED1, the second light emitting device ED2, and the third light emitting device ED3 may be formed to be separated.

Hereinafter, a structure of the pixel undercut area PUCA where the pixel electrode layer PEL is disconnected will be described in more detail.

The first color filter CF2 may include a portion CF1_EA located in the first emission area EA1 and an extended portion CF1_EXT extended beyond the first emission area EA1 toward the circuit area of another adjacent sub-pixel. The first color filter CF2 may not extend to the first circuit area CA1.

The pixel electrode layer PEL may be disconnected in the vicinity of the extended portion CF1_EXT of the first color filter CF1. The vicinity of the extended portion CF1_EXT of the first color filter CF1 may correspond to the first pixel undercut area PUCA1.

The second color filter CF2 may include a portion CF2_EA located in the second emission area EA2 and am extended portion CF2_EXT extended beyond the second emission area EA2 toward the first circuit area CA1. The second color filter CF2 may not extend to the second circuit area CA2.

The pixel electrode layer PEL may be disconnected in the vicinity of the extended portion CF2_EXT of the second color filter CF2. The vicinity of the extended portion CF2_EXT of the second color filter CF2 may correspond to the second pixel undercut area PUCA2.

The third color filter CF3 may include a portion CF3_EA located in the third emission area EA3 and an extended portion CF3_EXT extended beyond the third emission area EA3 toward the second circuit area CA2. The third color filter CF3 may not extend to the third circuit area CA4.

The pixel electrode layer PEL may be disconnected in the vicinity of the extended portion CF3_EXT of the third color filter CF3. The vicinity of the extended portion CF3_EXT of the third color filter CF3 may correspond to the third pixel undercut area PUCA3.

The display panel 110 according to the embodiments of the present disclosure may further include a first bottom metal BMT1 located below the extended portion CF1_EXT of the first color filter CF1, a second bottom metal BMT2 located below the extended portion CF2_EXT of the second color filter CF2, and a third bottom metal BMT3 located below the extended portion CF3_EXT of the third color filter CF3.

The first bottom metal BMT1 is located under the extended portion CF1_EXT of the first color filter CF1, so that the pixel electrode layer PEL may be more easily disconnected near the extended portion CF1_EXT of the first color filter CF1.

By positioning the second bottom metal BMT2 under the extended portion CF2_EXT of the second color filter CF2, the pixel electrode layer PEL may be more easily disconnected near the extended portion CF2_EXT of the second color filter CF2.

By positioning the third bottom metal BMT3 under the extended portion CF3_EXT of the third color filter CF3, the pixel electrode layer PEL may be more easily disconnected near the extended portion CF3_EXT of the third color filter CF3.

The first to third bottom metals BMT1, BMT2 and BMT3 may correspond to signal line that supplies a signal having a constant voltage level over time to the first to third sub-pixel circuits SPC1, SPC2 and SPC3. For example, the first to third bottom metals BMT1, BMT2 and BMT3 may be the first to third branch signal lines VDDL_BRC1, VDDL_BRC2 and VDDL_BRC3 of FIG. 4.

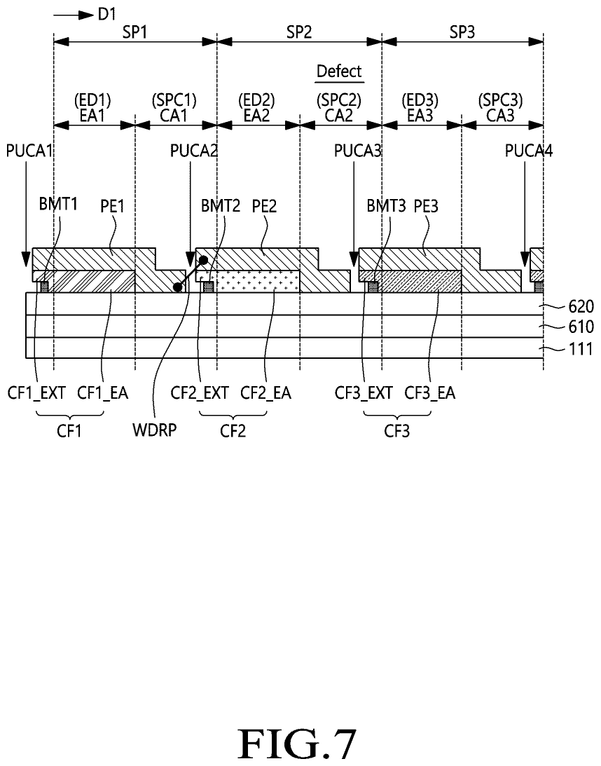

FIG. 7 is another cross-sectional view of the display panel 110 in which the first to third sub-pixels SP1, SP2 and SP3 are arranged according to embodiments of the present disclosure. In the following description, FIG. 6 will be also referred to. In addition, descriptions of contents that overlap with those explained with reference to FIG. 6 may be omitted.

Referring to FIG. 7, if a defect occurs in the second sub-pixel circuit SPC2 arranged in the second circuit area CA2 of the second sub-pixel SP2 during manufacturing the display panel 110, the defect may be detected through an inspection process, and repair processing may be performed on the second sub-pixel SP2.

When performing repair processing for the second sub-pixel SP2, the first pixel electrode PE1 and the second pixel electrode PE2 may be electrically connected. Here, the point where the first pixel electrode PE1 and the second pixel electrode PE2 are electrically connected may correspond to the second pixel undercut area PUCA2.

For example, as a result of the repair processing for the second sub-pixel SP2, the pixel electrode layer PEL may be connected near the extended portion CF2_EXT of the second color filter CF2.

The first pixel electrode PE1 and the second pixel electrode PE2 may be electrically connected by a welding repair pattern WDRP. The welding repair pattern WDRP may include a pixel electrode material.

As described above, after the repair process for the second sub-pixel SP2 is performed, the second light emitting device ED2 of the second sub-pixel SP2 may be driven by the first sub-pixel circuit SPC1 disposed in the first circuit area CA1 of the first sub-pixel SP1.

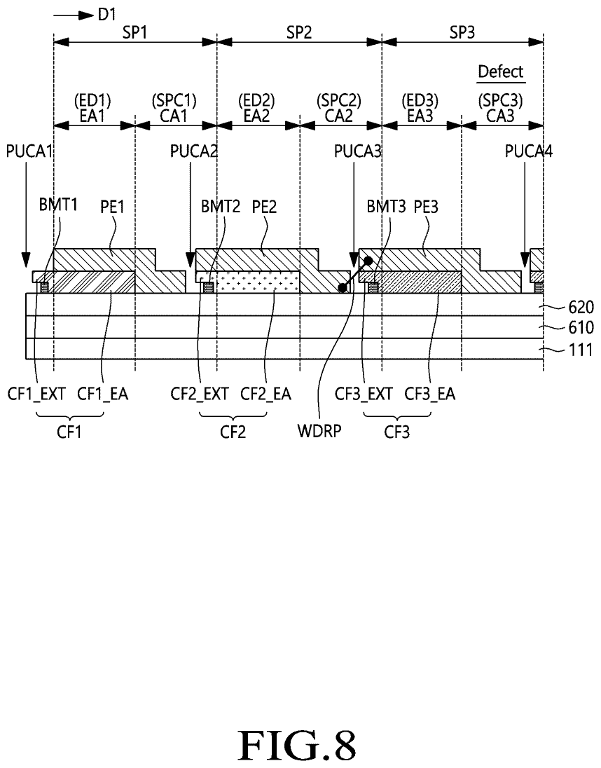

FIG. 8 is another cross-sectional view of the display panel 110 according to embodiments of the present disclosure in which the first to third sub-pixels SP1, SP2 and SP3 are disposed. In the following description, FIG. 6 is also referred to. In addition, description of content that overlaps with the content described with reference to FIG. 6 may be omitted.

Referring to FIG. 8, when manufacturing a display panel 110, if a defect occurs in the third sub-pixel circuit SPC3 located in the third circuit area CA3 of the third sub-pixel SP3, the defect may be detected through an inspection process, and repair processing may be performed on the third sub-pixel SP3.

When performing repair processing for the third sub-pixel SP3, the second pixel electrode PE2 and the third pixel electrode PE3 may be electrically connected. Here, the point where the second pixel electrode PE2 and the third pixel electrode PE3 are electrically connected may be the third pixel undercut area PUCA3.

For example, as a result of the repair processing for the third sub-pixel SP3, the pixel electrode layer PEL may be connected near the extended portion CF3_EXT of the third color filter CF3.

The second pixel electrode PE2 and the third pixel electrode PE3 may be electrically connected by a welding repair pattern WDRP. The welding repair pattern WDRP may include a pixel electrode material.

As described above, after the repair process for the third sub-pixel SP3 is performed, the third light emitting device ED3 of the third sub-pixel SP3 may be driven by the second sub-pixel circuit SPC2 arranged in the second circuit area CA2 of the second sub-pixel SP2.

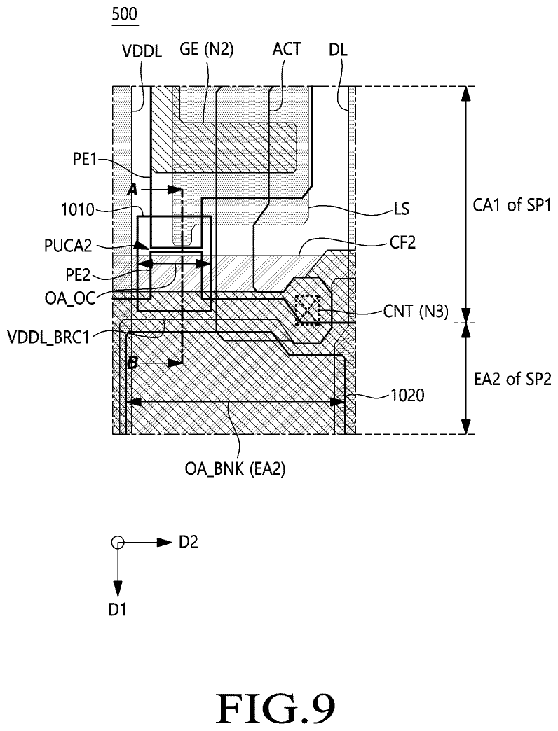

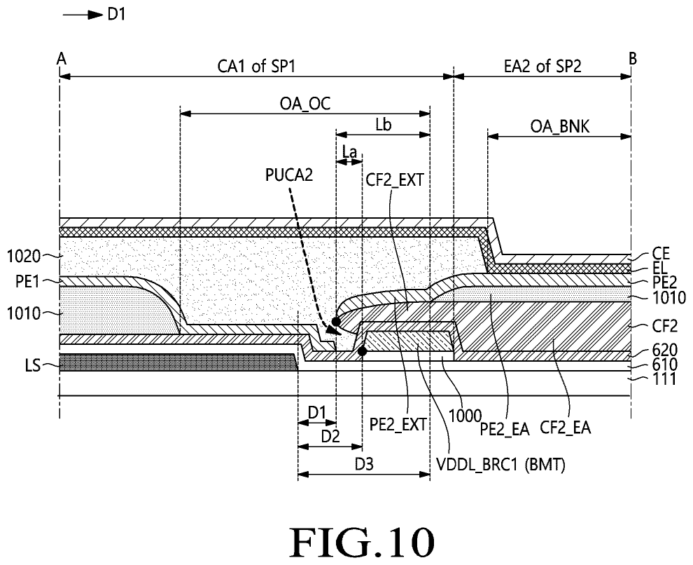

FIGS. 9 and 10 are a plan view and a cross-sectional view of a portion of a display panel 110 according to embodiments of the present disclosure. FIG. 9 is a plan view of a portion of an area 500 of FIG. 5. In addition, FIG. 10 is a cross-sectional view along the line A-B of FIG. 9. In the following description, FIGS. 1 to 8 are also referred to.

A first sub-pixel SP1 and a second sub-pixel SP2 may be disposed in a display area DA of the substrate 111. The first sub-pixel SP1 may include a first emission area EA1 and a first circuit area CA1, and the second sub-pixel SP2 may include a second emission area EA2 and a second circuit area CA2.

Referring to FIG. 9, in a part of the first circuit area CA1 of the first sub-pixel SP1, an active layer ACT of a driving transistor DRT included in a first sub-pixel circuit SPC1 of the first sub-pixel SP1 may be disposed, and a gate electrode GE of the driving transistor DRT may be disposed. The gate electrode GE of the driving transistor DRT may correspond to a second node N2 of the driving transistor DRT.

Referring to FIG. 9, a data line DL and a first common voltage line VDDL may be further arranged in a part of the first circuit area CA1. The data line DL and the first common voltage line VDDL may be extended in the first direction D1.

Referring to FIG. 9, a first branch signal line VDDL_BRC1 electrically connected to the first common voltage line VDDL may be further arranged in a part of the first circuit area CA1. The first branch signal line VDDL_BRC1 may be extended in the second direction D2.

Referring to FIG. 9, a part of the active layer ACT of the driving transistor DRT may be a conductive part. The conductive part of the active layer ACT of the driving transistor DRT may correspond to the third node N3 of the driving transistor DRT, and may be electrically connected to the first branch signal line VDDL_BRC1 through a contact hole CNT.

Referring to FIGS. 9 and 10, the display panel 110 according to the embodiments of the present disclosure may include a shielding pattern LS on a substrate 111, a protective layer 620 on the shielding pattern LS, a second color filter CF2 on the protective layer 620, a first pixel electrode PE1 on the protective layer 620, and a second pixel electrode PE2 on the second color filter CF2.

The shielding pattern LS may be disposed on the substrate 111 and may be located in the first circuit area CA1 of the first sub-pixel SP1. The shielding pattern LS may include the same metal as the data line DL and the first common voltage line VDDL. The shielding pattern LS may be disposed within the same metal layer as the data line DL and the first common voltage line VDDL.

The second color filter CF2 may be disposed on the protective layer 620 and located in the second emission area EA2 of the second sub-pixel SP2.

The second color filter CF2 may extend in the opposite direction to the first direction D1. That is, the second color filter CF2 may extend from the second emission area EA2 of the second sub-pixel SP2 toward the first circuit area CA1 of the first sub-pixel SP1.

The first pixel electrode PE1 is a pixel electrode for forming the first light emitting device ED1 of the first sub-pixel SP1, and may be disposed on the protective layer 620 and located in the first emission area EA1 of the first sub-pixel SP1.

The first pixel electrode PE1 may extend in the first direction D1. That is, the first pixel electrode PE1 may extend from the first emission area EA1 of the first sub-pixel SP1 to the first circuit area CA1 of the first sub-pixel SP1.

The second pixel electrode PE2 is a pixel electrode for forming the second light emitting device ED2 of the second sub-pixel SP1, and may be disposed on the second color filter CF2 and located in the second emission area EA2 of the second sub-pixel SP1.

The second pixel electrode PE2 may extend in the opposite direction to the first direction D1. That is, the second pixel electrode PE2 may extend from the second emission area EA2 of the second sub-pixel SP1 toward the first circuit area CA1 of the first sub-pixel SP1.

Referring to FIG. 10, the second color filter CF2 may include a main filter portion CF2_EA located in the second emission area EA2 and an extended filter portion CF2_EXT extended from the main filter portion CF2_EA toward the first circuit area CA1. For example, the extended filter portion CF2_EXT of the second color filter CF2 may be located in the first circuit area CA1 of the first sub-pixel SP1.

The main filter portion CF2_EA of the second color filter CF2 may overlap with the second emission area EA2. The extended filter portion CF2_EXT of the second color filter CF2 may not overlap with the second emission area EA2 but may overlap with an outer area of the second emission area EA2. For example, the extended filter portion CF2_EXT of the second color filter CF2 may overlap with the first circuit area CA1 of the first sub-pixel SP1.

Referring to FIG. 10, the second pixel electrode PE2 may include a main electrode portion PE2_EA located in the second emission area EA2 and an extended electrode portion PE2_EXT extending from the main electrode portion PE2_EA toward the first circuit area CA1. For example, the extended electrode portion PE2_EXT of the second pixel electrode PE2 may be located in the first circuit area CA1 of the first sub-pixel SP1.

The main electrode portion PE2_EA of the second pixel electrode PE2 may overlap with the second emission area EA2. The extended electrode portion PE2_EXT of the second pixel electrode PE2 may not overlap with the second emission area EA2 but may overlap with an outer area of the second emission area EA2. For example, the extended electrode portion PE2_EXT of the second pixel electrode PE2 may overlap with the first circuit area CA1 of the first sub-pixel SP1.

Referring to FIGS. 9 and 10, the first pixel electrode PE1 and the second pixel electrode PE2 may be electrically separated at or near the boundary between the first circuit area CA1 and the second emission area EA2. The area where the first pixel electrode PE1 and the second pixel electrode PE2 are electrically separated may correspond to the second pixel undercut area PUCA2.

In the display panel 110 according to the embodiments of the present disclosure, a structure in which the pixel electrode layer PEL is separated into the first pixel electrode PE1 and the second pixel electrode PE2 may be referred to as a “pixel undercut structure”.

The second pixel undercut area PUCA2 may be an outer area of the second emission area EA2. For example, as illustrated in FIGS. 9 and 10, the second pixel undercut area PUCA2 may be included in the first circuit area CA1.

Referring to FIGS. 9 and 10, the display panel 110 according to the embodiments of the present disclosure may further include a buffer layer 610 disposed between the substrate 111 and the protective layer 620, and a bottom metal BMT disposed between the substrate 111 and the buffer layer 610 and located in the first circuit area CA1.

The bottom metal BMT may correspond to a signal wiring that supplies a signal having a constant voltage level over time to the first sub-pixel SP1 and the second sub-pixel SP2. For example, the bottom metal BMT may be electrically connected to the first common voltage line VDDL extended in the first direction D1, and may be a first branch signal line VDDL_BRC1 extended in the second direction D2 different from the first direction D1.

Referring to FIGS. 9 and 10, a portion CF2_EXT of the second color filter CF2 extending toward the first circuit area CA1 may overlap with the bottom metal BMT. In the present disclosure, a portion of the second color filter CF2 extended toward the first circuit area CA1 may be an extended filter portion CF2_EXT of the second color filter CF2.

Referring to FIGS. 9 and 10, a portion PE2_EXT of the second pixel electrode extending toward the first circuit area CA1 may overlap with the bottom metal BMT. In the present disclosure, a portion of the second pixel electrode PE2 extended toward the first circuit area CA1 may be an extended electrode portion PE2_EXT of the second pixel electrode PE2.

The first circuit area CA1 of the first sub-pixel SP1 may include a transistor including a source electrode, a drain electrode, a gate electrode, and an active layer. Here, the transistor may be one of a driving transistor DRT, a scan transistor SCT, and a sensing transistor SENT.

The display panel 110 may further include a gate insulating layer 1000 between the active layer and the gate electrode. The bottom metal BMT may include the same metal as the gate electrode. For example, the bottom metal BMT may include the same metal as a gate electrode GE of the driving transistor DRT.

The bottom metal BMT may be disposed within the same metal layer as the gate electrode. Therefore, as illustrated in FIG. 10, the gate insulating layer 1000 may be further disposed between the protective layer 620 and the bottom metal BMT.

Referring to FIG. 10, the second pixel electrode PE2 may include a main electrode portion PE2_EA located in the second emission area EA2 and an extended electrode portion PE2_EXT extending from the main electrode portion PE2_EA toward the first circuit area CA1. At least a portion of the extended electrode portion PE2_EXT may overlap with the bottom metal BMT.

Referring to FIG. 10, the second color filter CF2 may include a main filter portion CF2_EA located in the second emission area EA2 and an extended filter portion CF2_EXT extending from the main filter portion CF2_EA toward the first circuit area CA1. At least a portion of the extended filter portion CF2_EXT may overlap with the bottom metal BMT.

Referring to FIGS. 9 and 10, the display panel 110 may further include a bank 1020 disposed on at least a portion of the first pixel electrode PE1 and on at least a portion of the extended electrode portion PE2_EXT of the second pixel electrode PE2. The bank 1020 may have an opening OA_BNK overlapping with the second emission area EA2.

Referring to FIG. 10, the bank 1020 may be interposed between the upper surface of the protective layer 620 and the back surface of the end of the extended filter portion CF2_EXT of the second color filter CF2. That is, the bank 1020 may be interposed in a sunken space below the back surface of the extended filter portion CF2_EXT of the second color filter CF2. The surrounding area of the space between the upper surface of the protective layer 620 and the back surface of the end of the extended filter portion CF2_EXT of the second color filter CF2 (i.e., the sunken space below the back surface of the extended filter portion CF2_EXT of the second color filter CF2) may be a second pixel undercut area PUCA2.

Referring to FIG. 10, in the surrounding area of the space between the upper surface of the protective layer 620 and the back surface of the end of the extended filter portion CF2_EXT of the second color filter CF2 (i.e., the sunken space below the back surface of the extended filter portion CF2_EXT of the second color filter CF2), the first pixel electrode PE1 and the second pixel electrode PE2 may be separated from each other.

Referring to FIGS. 9 and 10, the display panel 110 according to the embodiments of the present disclosure may further include an overcoat layer 1010 disposed between at least a portion of the second pixel electrode PE2 and the second color filter CF2.

Referring to FIGS. 9 and 10, the overcoat layer 1010 may have an opening OA_OC that overlaps with the second pixel undercut area PUCA2. The opening OA_OC of the overcoat layer 1010 may overlap with a portion of the first pixel electrode PE1 and a portion of the second pixel electrode PE2.

The opening OA_OC of the overcoat layer 1010 may overlap with an extended filter portion CF2_EXT of the second color filter CF2.

Referring to FIG. 10, a distance D2 between the bottom metal BMT and the shielding pattern LS may be greater than or equal to a distance D1 between the second color filter CF2 and the shielding pattern LS.

A distance La between an edge of the bottom metal BMT and an edge of the second color filter CF2 may be greater than or equal to zero and less than or equal to a threshold distance value. Here, the edge of the bottom metal BMT may be an edge closer to the shielding pattern LS among the edges of both sides of the bottom metal BMT. The threshold distance value may be a distance Lb between the edge of the second color filter CF2 and the edge of the overcoat layer 1010 on the second color filter CF2.

Referring to FIG. 10, the distance Lb between the edge of the second color filter CF2 and the edge of the overcoat layer 1010 on the second color filter CF2 may be greater than or equal to zero.

Referring to FIG. 10, the edge of the bottom metal BMT may be located between the edge of the second color filter CF2 and the edge of the overcoat layer 1010 on the second color filter CF2.

Referring to FIG. 10, the distance D1 between the second color filter CF2 and the shielding pattern LS may be less than or equal to a distance D3 between the overcoat layer 1010 and the shielding pattern LS.

Referring to FIG. 10, the distance D2 between the bottom metal BMT and the shielding pattern LS may be greater than or equal to the distance D1 between the second color filter CF2 and the shielding pattern LS and less than or equal to the distance D3 between the overcoat layer 1010 and the shielding pattern LS.

Accordingly, when the pixel electrode layer PEL is deposited during the panel manufacturing process, the pixel electrode layer may be easily cut off at the second pixel undercut area PUCA2. As a result, the pixel electrode layer PEL may be separated into the first pixel electrode PE1 and the second pixel electrode PE2.

Meanwhile, during the panel manufacturing process, if the second sub-pixel circuit SPC2 disposed in the second circuit area CA2 of the second sub-pixel SP2 is confirmed to be normal, repair processing for the second sub-pixel SP2 is not performed.

If the repair process is not performed, at the edge of the portion CF2_EXT extended toward the first circuit area CA1 in the second color filter CF2, i.e., in the second pixel undercut area PUCA2, the first pixel electrode PE1 and the second pixel electrode PE2 may be electrically separated.

Accordingly, the first pixel electrode PE1 and the second pixel electrode PE2 may be electrically connected to different sub-pixel circuits. That is, the first pixel electrode PE1 may be electrically connected to the first sub-pixel circuit SPC1 arranged in the first circuit area CA1 of the first sub-pixel SP1, and the second pixel electrode PE2 may be electrically connected to the second sub-pixel circuit SPC2 arranged in the second circuit area CA2 of the second sub-pixel SP2. Accordingly, the first pixel electrode PE1 and the second pixel electrode PE2 may be electrically connected to different transistors (e.g., driving transistors).

Meanwhile, during the panel manufacturing process, the second sub-pixel circuit SPC2 arranged in the second circuit area CA2 of the second sub-pixel SP2 may be confirmed as defective. If the second sub-pixel circuit SPC2 has a defect, the driving current may not be supplied from the second sub-pixel circuit SPC2 to the second pixel electrode PE2, or an abnormal driving current may be supplied. Therefore, during the panel manufacturing process, if the second sub-pixel circuit SPC2 arranged in the second circuit area CA2 of the second sub-pixel SP2 is confirmed as defective, repair processing may be performed on the second sub-pixel SP2.

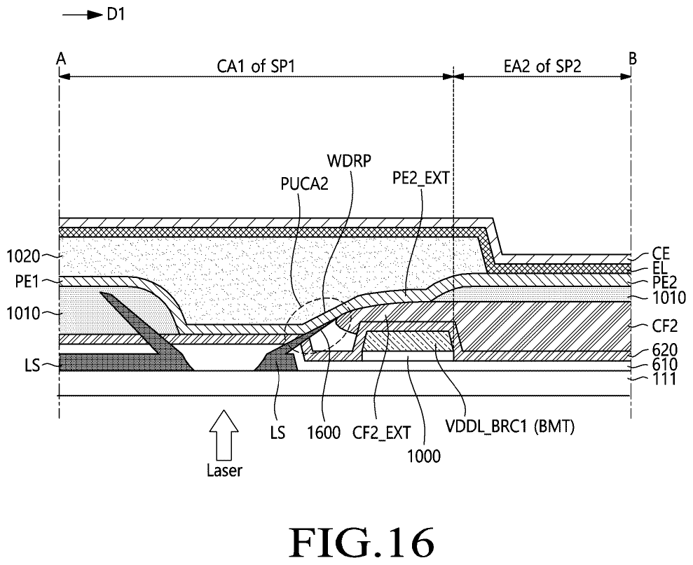

According to a welding process which is one of the repair processes for the second sub-pixel SP2, at the edge of the portion CF2_EXT extended toward the first circuit area CA1 in the second color filter CF2, i.e., in the second pixel undercut area PUCA2, the first pixel electrode PE1 and the second pixel electrode PE2 may be electrically connected (see FIG. 16).

According to a cutting process, which is another of the repair processes for the second sub-pixel SP2, the electrical connection of the second pixel electrode PE2 with the second sub-pixel circuit SPC2 arranged in the second circuit area CA2 of the second sub-pixel SP2 may be disconnected.

As the repair process for the second sub-pixel SP2 is performed, the second pixel electrode PE2 may be electrically connected to the first sub-pixel circuit SPC1 of the first sub-pixel SP1 and not connected to the second sub-pixel circuit SPC2 of the second sub-pixel SP2.

Accordingly, the driving current output from the first sub-pixel circuit SPC1 may be supplied to both the first pixel electrode PE1 and the second pixel electrode PE2. That is, the first sub-pixel circuit SPC1 may control both the first light emitting device ED1 of the first sub-pixel SP1 and the second light emitting device ED2 of the second sub-pixel SP2 to emit light.

Both the first pixel electrode PE1 and the second pixel electrode PE2 may be electrically connected to the first sub-pixel circuit SPC1 disposed in the first circuit area CA1 of the first sub-pixel SP1. Therefore, the first pixel electrode PE1 and the second pixel electrode PE2 may be electrically connected to the same transistor (for example, a driving transistor included in the first sub-pixel circuit SPC1).

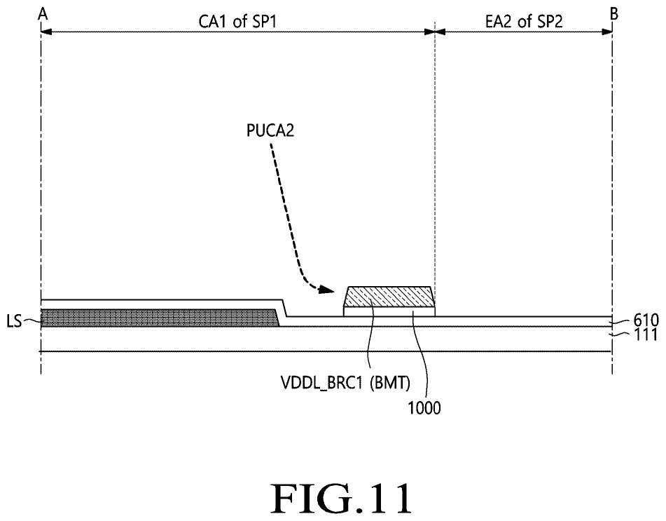

FIGS. 11 to 15 illustrate a manufacturing procedure of a display panel 110 according to embodiments of the present disclosure.

Referring to FIG. 11, in a first step (S10), a buffer layer 610 may be disposed on a substrate 111, and a shielding pattern LS may be disposed on the buffer layer 610. The shielding pattern LS may be located in the first circuit area CA1 of the first sub-pixel SP1.

In the first step (S10), a gate insulating layer 1000 may be disposed on a buffer layer 610, and a bottom metal BMT serving as a first branch signal line VDDL_BRC may be disposed on the gate insulating layer 1000.

In order to form a pixel undercut structure in the second pixel undercut area PUCA2, the bottom metal BMT may be formed in a predetermined specific region.

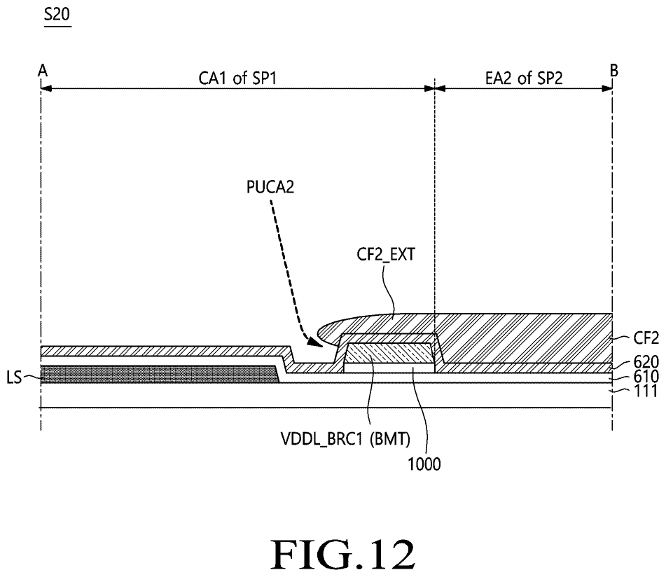

Referring to FIG. 12, in a second step (S20), a protective layer 620 may be disposed on the bottom metal BMT, and a second color filter CF2 may be disposed on the protective layer 620.

The second color filter CF2 may be located in the second emission area EA2 of the second sub-pixel SP2, but may be disposed so as to extend to the first circuit area CA1 of the first sub-pixel SP1. At this time, the second color filter CF2 may extend to the edge of the bottom metal BMT, or may extend further than the bottom metal BMT.

The extended filter portion CF2_EXT of the second color filter CF2 may overlap with the bottom metal BMT.

In the second step (S20), the extended filter portion CF2_EXT of the second color filter CF2 may be located higher than the surroundings thereof, and the lower portion of the back surface of the extended filter portion CF2_EXT of the second color filter CF2 may have a sunken structure. This structure may correspond to a pixel undercut structure.

Referring to FIG. 12, in the second step (S20), the lower portion of the extended filter portion CF2_EXT of the second color filter CF2 may be sunken, thereby more effectively forming the pixel undercut structure.

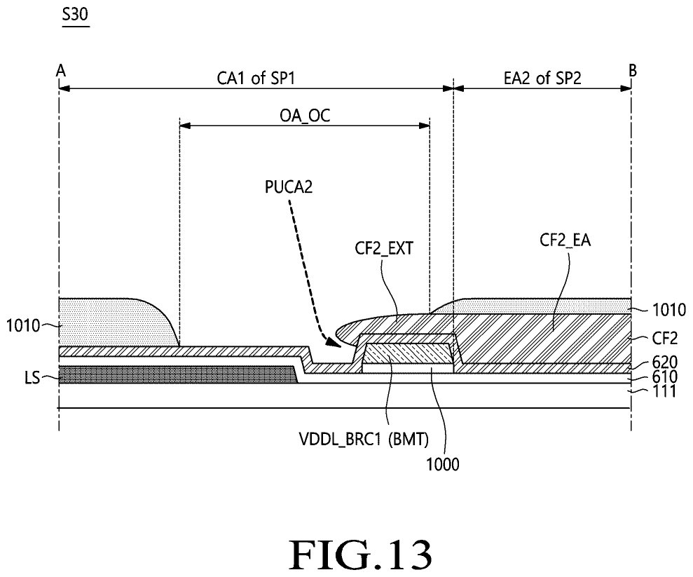

Referring to FIG. 13, in a third step (S30), an overcoat layer 1010 may be disposed on the protective layer 620 and the second color filter CF2.

The overcoat layer 1010 may have an opening OA_OC. The opening OA_OC of the overcoat layer 1010 may overlap with the second pixel undercut area PUCA2. The opening OA_OC of the overcoat layer 1010 may overlap with the extended filter portion CF2_EXT of the second color filter CF2.

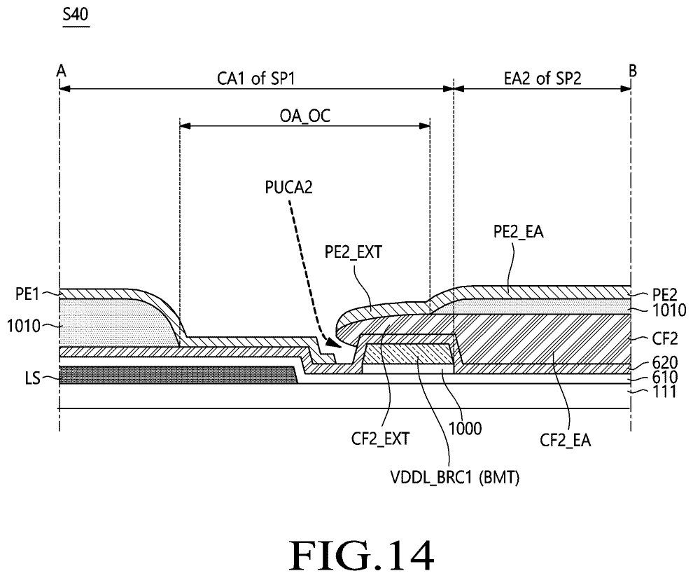

Referring to FIG. 14, in a fourth step (S40), a pixel electrode layer PEL may be formed on the second color filter CF2.

Due to the pixel undercut structure in the second pixel undercut area PUCA2, the pixel electrode layer PEL may be cut off or disconnected near the extended filter portion CF2_EXT of the second color filter CF2. Accordingly, the pixel electrode layer PEL may be naturally separated into the first pixel electrode PE1 and the second pixel electrode PE2.

Here, the pixel undercut structure may be a structure in which the extended portion CF2_EXT of the second color filter CF2 is located higher than its surroundings, and the lower portion of the back surface of the extended portion CF2_EXT of the second color filter CF2 is sunken.

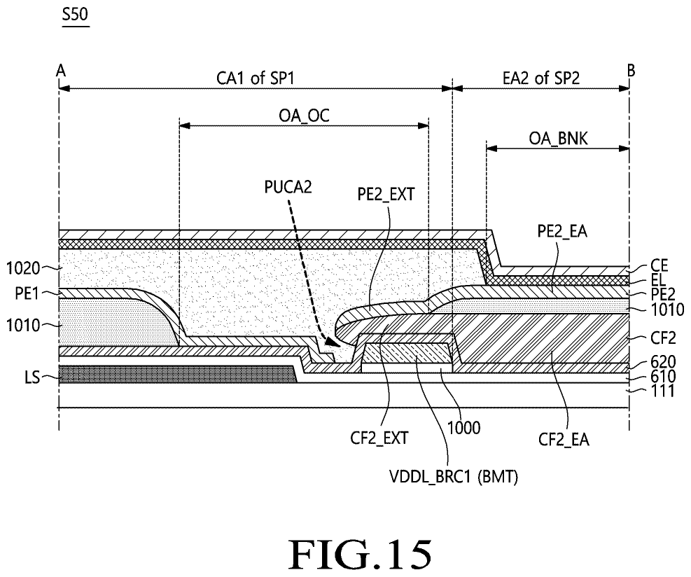

Referring to FIG. 15, in a fifth step (S50), a bank 1020 may be disposed on the first pixel electrode PE1 and the second pixel electrode PE2. The bank 1020 may have an opening OA_BNK that overlaps with a portion of the second pixel electrode PE2 (e.g., a portion for forming the second light emitting device ED2).

The bank 1020 may overlap with the second pixel undercut area PUCA2.

In the fifth step (S50), an intermediate layer EL may be disposed on the second pixel electrode PE2 and may be extended to the upper portion of the bank 1020. A common electrode CE may be disposed on the intermediate layer EL.

FIG. 16 is a cross-sectional view of a portion of a display panel 110 according to embodiments of the present disclosure. FIGS. 1 to 10 are also referred to in the following description.

During the panel manufacturing process, the second sub-pixel circuit SPC2 arranged in the second circuit area CA2 of the second sub-pixel SP2 may be confirmed as defective. If the second sub-pixel circuit SPC2 is defective, the driving current may not be supplied from the second sub-pixel circuit SPC2 to the second pixel electrode PE2 or an abnormal driving current may be supplied. Therefore, during the panel manufacturing process, if the second sub-pixel circuit SPC2 arranged in the second circuit area CA2 of the second sub-pixel SP2 is confirmed as defective, repair processing may be performed on the second sub-pixel SP2.

According to a welding process, which is one of the repair processes for the second sub-pixel SP2, at the edge of the portion CF2_EXT extended toward the first circuit area CA1 in the second color filter CF2, i.e., in the second pixel undercut area PUCA2, the first pixel electrode PE1 and the second pixel electrode PE2 may be electrically connected.

According to a cutting process, which is another of the repair processes for the second sub-pixel SP2, the second pixel electrode PE2 may be electrically disconnected from the second sub-pixel circuit SPC2 arranged in the second circuit area CA2 of the second sub-pixel SP2.

As the repair process for the second sub-pixel SP2 is performed, the second pixel electrode PE2 may be electrically connected to the first sub-pixel circuit SPC1 of the first sub-pixel SP1 and not connected to the second sub-pixel circuit SPC2 of the second sub-pixel SP2.

Accordingly, the driving current output from the first sub-pixel circuit SPC1 may be supplied to both the first pixel electrode PE1 and the second pixel electrode PE2. That is, the first sub-pixel circuit SPC1 may cause both the first light emitting device ED1 of the first sub-pixel SP1 and the second light emitting device ED2 of the second sub-pixel SP2 to emit light.

Both the first pixel electrode PE1 and the second pixel electrode PE2 may be electrically connected to the first sub-pixel circuit SPC1 arranged in the first circuit area CA1 of the first sub-pixel SP1. Accordingly, the first pixel electrode PE1 and the second pixel electrode PE2 may be electrically connected to the same transistor (for example, a driving transistor included in the first sub-pixel circuit SPC1).

It will be described a welding process, which is one of the repair processes for the second sub-pixel SP2, and the result thereof in more detail.

Referring to FIG. 16, when performing the welding process as one of the repair processes for the second sub-pixel SP2, a laser may be irradiated toward the shielding pattern LS from under the substrate 111.

According to the welding process using the laser, at the edge of the portion CF2_EXT extended toward the first circuit area CA1 in the second color filter CF2, i.e., in the second pixel undercut area PUCA2, the first pixel electrode PE1 and the second pixel electrode PE2 may be electrically connected.

The first pixel electrode PE1 and the second pixel electrode PE2 may be electrically connected by the welding repair pattern WDRP. The welding repair pattern WDRP may include a pixel electrode material.

Referring to FIG. 16, a metal fragment 1600 may exist near the edge of a portion CF2_EXT extended toward the first circuit area CA1 in the second color filter CF2.

The metal fragment 1600 may electrically connect the first pixel electrode PE1 and the second pixel electrode PE2, or may be placed under a portion where the first pixel electrode PE1 and the second pixel electrode PE2 are connected. The metal fragment 1600 may be a welding repair pattern WDRP that substantially connects the first pixel electrode PE1 and the second pixel electrode PE2.

Referring to FIG. 16, the shielding pattern LS may burst or rupture in the welding process using a laser, so that the metal fragment 1600 of the shielding pattern LS may rise upward. Accordingly, a part of the first pixel electrode PE1 may be lifted and connected to the second pixel electrode PE2. Accordingly, the metal fragment 1600 may be connected to the shielding pattern LS or may include the same material as the shielding pattern LS. The metal fragment 1600 may correspond to a ruptured portion of the shielding pattern LS.

Embodiments of the present disclosure described above are briefly described as follows.

A display device according to embodiments of the present disclosure may include a substrate, a display area in which a first sub-pixel including a first emission area and a first circuit area and a second sub-pixel including a second emission area and a second circuit area are disposed, a shielding pattern disposed on the substrate and located in the first circuit area, a protective layer on the shielding pattern, a color filter disposed on the protective layer, located in the second emission area, and extending from the second emission area toward the first circuit area, a first pixel electrode disposed on the protective layer, located in the first emission area, and extending from the first emission area toward the first circuit area, and a second pixel electrode disposed on the color filter, located in the second emission area, and extending from the second emission area toward the first circuit area.

The display device according to embodiments of the present disclosure may further include a buffer layer disposed between the substrate and the protective layer, and a bottom metal disposed between the substrate and the buffer layer, and located in the first circuit area.

A portion extended toward the first circuit area in the color filter may overlap with the bottom metal. A portion extended toward the first circuit area in the second pixel electrode may overlap with the bottom metal.

The display device according to embodiments of the present disclosure may further include a common voltage line that supplies a common voltage to the first sub-pixel and the second sub-pixel and extends in a first direction. The bottom metal may be electrically connected to the common voltage line, and may extend in a second direction different from the first direction.

The bottom metal may include the same metal as a gate electrode of a transistor included in the first sub-pixel and the second sub-pixel.

A distance between the bottom metal and the shielding pattern may be greater than or equal to a distance between the color filter and the shielding pattern.

The second pixel electrode may include a main electrode portion located in the second emission area, and an extended electrode portion extended from the main electrode portion toward the first circuit area. A part of the extended electrode portion may overlap with the bottom metal.

The color filter may include a main filter portion located in the second emission area, and an extended filter portion extended from the main filter portion toward the first circuit area.

At least a part of the extended filter portion may overlap with the bottom metal.

The display device according to embodiments of the present disclosure may further include a bank disposed on at least a portion of the first pixel electrode and on at least a portion of the extended electrode portion of the second pixel electrode.

The bank may be interposed in a sunken space below a back surface of the extended filter portion of the second color filter. That is, the bank may be interposed in the space below the back surface of the extended filter portion of the second color filter.

The first pixel electrode and the second pixel electrode may be separated around the sunken space below the back surface of the extended filter portion of the second color filter.

The display device according to embodiments of the present disclosure may further include an overcoat layer disposed between at least a portion of the second pixel electrode and the color filter.

The overcoat layer may have an opening overlapping with an extended portion of the color filter.

A distance between the color filter and the shielding pattern may be less than or equal to a distance between the overcoat layer and the shielding pattern.

A distance between the bottom metal and the shielding pattern is greater than or equal to a distance between the color filter and the shielding pattern, and may be less than or equal to a distance between the overcoat layer and the shielding pattern.

The first pixel electrode and the second pixel electrode may be electrically separated at an edge of a portion extending toward the first circuit area in the color filter.

If the first pixel electrode and the second pixel electrode are electrically separated at an edge of a portion extending toward the first circuit area in the color filter, the first pixel electrode and the second pixel electrode may be electrically connected to different transistors.

The first sub-pixel may include a first sub-pixel circuit disposed in a first circuit area, and the second sub-pixel may include a second sub-pixel circuit disposed in a second circuit area. If the first pixel electrode and the second pixel electrode are electrically separated at an edge of a portion extending toward the first circuit area in the color filter, the first pixel electrode may be connected to the first sub-pixel circuit, and the second pixel electrode may be connected to the second sub-pixel circuit.

The first pixel electrode and the second pixel electrode may be electrically connected to each other at an edge of a portion extending toward the first circuit area in the color filter.

If the first pixel electrode and the second pixel electrode are electrically connected to each other at an edge of a portion extending toward the first circuit area in the color filter, there may be additional metal fragments located near the edge of the portion extending toward the first circuit area in the color filter.

The metal fragment may electrically connect the first pixel electrode and the second pixel electrode, or may be disposed below a portion where the first pixel electrode and the second pixel electrode are connected.

The metal fragment may be connected to the shielding pattern, or include the same material as the shielding pattern. For example, the metal fragment may correspond to a ruptured portion of the shielding pattern.

If the first pixel electrode and the second pixel electrode are electrically connected to each other at an edge of a portion extending toward the first circuit area in the color filter, the first pixel electrode and the second pixel electrode may be electrically connected to the same transistor.

If the first pixel electrode and the second pixel electrode are electrically connected to each other at an edge of a portion extending toward the first circuit area in the color filter, the first pixel electrode may be connected to the first sub-pixel circuit, and the second pixel electrode may be connected to the first sub-pixel circuit and may be disconnected from the second sub-pixel circuit.

A display device according to embodiments of the present disclosure may include a first color filter located in a first emission area of a first sub-pixel, a first sub-pixel circuit located in a first circuit area of the first sub-pixel, a second color filter located in a second emission area of a second sub-pixel adjacent to the first sub-pixel in a first direction, a second sub-pixel circuit located in a second circuit area of the second sub-pixel, and a pixel electrode layer located in the first emission area, the first circuit area, the second emission area, and the second circuit area.

The second color filter may include an extended portion extending beyond the second emission area toward the first circuit area.

The pixel electrode layer may be disconnected near the extended portion of the second color filter.

The display device according to embodiments of the present disclosure may further include a bottom metal disposed below the extended portion of the second color filter.

The bottom metal may correspond to a signal line that supplies a signal having a constant voltage level over time to the first sub-pixel circuit and the second sub-pixel circuit.

The display device according to embodiments of the present disclosure may further include a third color filter located in a third emission area of a third sub-pixel adjacent to the second sub-pixel in the first direction, and a third sub-pixel circuit located in a third circuit area of the third sub-pixel.

The pixel electrode layer may be disposed in the first emission area, the first circuit area, the second emission area, the second circuit area, the third emission area, and the third circuit area.

The third color filter may include an extended portion extending beyond the third emission area toward the second circuit area.

The pixel electrode layer may be connected near the extended portion of the third color filter.

According to the embodiments of the present disclosure described above, it is possible to provide a display device having a structure that enables repair processing to normalize a defective sub-pixel.

According to embodiments of the present disclosure, it is possible to provide a display device having a structure that enables repair processing without reducing the aperture ratio.

According to embodiments of the present disclosure, it is possible to provide a high resolution display device capable of repair processing.

According to embodiments of the present disclosure, it is possible to provide a display device capable of utilizing a pattern (e.g., shielding pattern) formed for display as a repair pattern.

According to embodiments of the present disclosure, it is possible to provide a display device capable of manufacturing a display panel into a good product through a repair processing of a defective sub-pixel in the manufacturing process, thereby increasing the panel manufacturing yield, saving production energy, and enabling process optimization.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention. The scope of protection of the present disclosure should be construed based on the following claims, and all technical features within the scope of equivalents thereof should be construed as being included within the scope of the present disclosure.

What is claimed is:

1. A display device, comprising:
a substrate;
a display area in which a first sub-pixel including a first emission area and a first circuit area and a second sub-pixel including a second emission area and a second circuit area are disposed;
a shielding pattern disposed on the substrate and located in the first circuit area;
a protective layer on the shielding pattern;
a color filter disposed on the protective layer, located in the second emission area, and extending from the second emission area toward the first circuit area;
a first pixel electrode disposed on the protective layer, located in the first emission area, and extending from the first emission area toward the first circuit area; and
a second pixel electrode disposed on the color filter, located in the second emission area, and extending from the second emission area toward the first circuit area.

2. The display device of claim 1, further comprising:
a buffer layer disposed between the substrate and the protective layer; and
a bottom metal disposed between the substrate and the buffer layer, and located in the first circuit area,
wherein, in the color filter, a portion extended toward the first circuit area overlaps with the bottom metal, and
wherein, in the second pixel electrode, a portion extended toward the first circuit area overlaps with the bottom metal.

3. The display device of claim 2, further comprising a common voltage line that is configured to supply a common voltage to the first sub-pixel and the second sub-pixel and extends in a first direction,
wherein the bottom metal is electrically connected to the common voltage line and extends in a second direction different from the first direction.

4. The display device of claim 2, wherein the bottom metal includes a same metal as a gate electrode of a transistor included in the first sub-pixel and the second sub-pixel.

5. The display device of claim 2, wherein a distance between the bottom metal and the shielding pattern is greater than or equal to a distance between the color filter and the shielding pattern.

6. The display device of claim 2, wherein the second pixel electrode includes a main electrode portion located in the second emission area, and an extended electrode portion extended from the main electrode portion toward the first circuit area,
wherein at least a part of the extended electrode portion overlaps with the bottom metal,
wherein the color filter includes a main filter portion located in the second emission area, and an extended filter portion extended from the main filter portion toward the first circuit area,
wherein at least a part of the extended filter portion overlaps with the bottom metal, and
wherein the display device further comprises a bank disposed on at least a portion of the first pixel electrode and on at least a portion of the extended electrode portion of the second pixel electrode.

7. The display device of claim 6, wherein the bank is interposed in a sunken space below a back surface of the extended filter portion of a second color filter.

8. The display device of claim 7, wherein the first pixel electrode and the second pixel electrode are separated around the sunken space below the back surface of the extended filter portion of the second color filter.

9. The display device of claim 2, further comprising an overcoat layer disposed between at least a portion of the second pixel electrode and the color filter,
wherein the overcoat layer includes an opening overlapping with an extended portion of the color filter.

10. The display device of claim 9, wherein a distance between the bottom metal and the shielding pattern is greater than or equal to a distance between the color filter and the shielding pattern, and less than or equal to a distance between the overcoat layer and the shielding pattern.

11. The display device of claim 1, wherein the first pixel electrode and the second pixel electrode are electrically separated at an edge of a portion extending toward the first circuit area in the color filter.

12. The display device of claim 11, wherein the first pixel electrode and the second pixel electrode are electrically connected to different transistors.

13. The display device of claim 1, wherein the first pixel electrode and the second pixel electrode are electrically connected to each other at an edge of a portion extending toward the first circuit area in the color filter.

14. The display device of claim 13, further comprising a metal fragment placed near the edge of the portion extending toward the first circuit area in the color filter,
wherein the metal fragment electrically connects the first pixel electrode and the second pixel electrode, or is disposed below a portion where the first pixel electrode and the second pixel electrode are connected, and
wherein the metal fragment is connected to the shielding pattern, or includes a same material as the shielding pattern.

15. The display device of claim 14, wherein the metal fragment corresponds to a ruptured portion of the shielding pattern.

16. The display device of claim 13, wherein the first pixel electrode and the second pixel electrode are electrically connected to a same transistor.

17. A display device, comprising:
a first color filter located in a first emission area of a first sub-pixel;
a first sub-pixel circuit located in a first circuit area of the first sub-pixel;
a second color filter located in a second emission area of a second sub-pixel adjacent to the first sub-pixel in a first direction;
a second sub-pixel circuit located in a second circuit area of the second sub-pixel; and
a pixel electrode layer located in the first emission area, the first circuit area, the second emission area, and the second circuit area,
wherein the second color filter includes an extended portion extending beyond the second emission area toward the first circuit area, and
wherein the pixel electrode layer is disconnected near the extended portion of the second color filter.

18. The display device of claim 17, further comprising a bottom metal disposed below the extended portion of the second color filter.

19. The display device of claim 18, wherein the bottom metal is configured to supply a signal having a constant voltage level over time to the first sub-pixel circuit and the second sub-pixel circuit.

20. The display device of claim 17, further comprising:
a third color filter located in a third emission area of a third sub-pixel adjacent to the second sub-pixel in the first direction; and
a third sub-pixel circuit located in a third circuit area of the third sub-pixel,
wherein the pixel electrode layer is disposed in the first emission area, the first circuit area, the second emission area, the second circuit area, the third emission area, and the third circuit area,
wherein the third color filter includes an extended portion extending beyond the third emission area toward the second circuit area, and
wherein the pixel electrode layer is connected near the extended portion of the third color filter.
